(19) United States
(12) Patent Application Publication
(10) Pub. No.: US 2024/0140624 A1
(43) Pub. Date: May 2, 2024

(54) DRONE INTEGRATED CONTROL DEVICE

(71) Applicant: Ha Na LEE, Jeonju-si (KR)

(72) Inventors: Ha Na LEE, Jeonju-si (KR); Jong Jin LEE, Jeonju-si (KR)

(21) Appl. No.: 18/406,214

(22) Filed: Jan. 8, 2024

Related U.S. Application Data
(63) Continuation of application No. PCT/KR2022/010586, filed on Jul. 20, 2022.

(30) Foreign Application Priority Data
Jul. 20, 2021 (KR) 10-2021-0095169

(51) Int. Cl. B64U 20/80; G05D 1/86

(52) U.S. Cl. CPC B64U 20/80; G05D 1/86; B64U 2201/00

(57) ABSTRACT

A drone integrated control device that controls a drone by unifying respective components on one board includes a flight control unit including a plurality of sensors and configured to control a path and a flight attitude of the drone, a motor control unit configured to control a rotation speed of at least one motor mounted to perform movements and takeoffs of the drone, a communication unit configured to transmit and receive control signals input to and output from the respective components included in the drone integrated control device, and a power supply unit configured to supply power to the respective components included in the drone integrated control device to operate the respective components.

### TECHNICAL FIELD

The present invention relates to a drone integrated control device, and more particularly, a drone integrated control device that controls a drone by unifying drone control devices, such as a flight control device, a motor control device, and a communication device, on one board.

### BACKGROUND ART

Recently, a drone industry using drones has grown rapidly, and the drones are being used in various fields, such as public infrastructure, transportation, agriculture, and media.

The drones are generally operated by receiving user manipulation signals wirelessly, and the devices included in the drones are becoming more and more diverse depending on operational purposes required in each field.

For example, in the related art, Korean Patent Publication No. 10-2018-0060403 (publication number) “CONTROL APPARATUS FOR DRONE BASED ON IMAGE” and Korean Patent No. 10-1895343 (registration number) “COLLISION AVOIDANCE APPARATUS FOR VEHICLES” are disclosed.

These drones are equipped with all devices separately, and accordingly, a user has to directly connect each device to the drone, and as a result, the wiring becomes complicated, and as the wiring becomes more complicated, incorrect assembly causes problems, such as a problem that the drone does not operate and a problem in which malfunctions occur due to interference to signals because the signals transmitted and received by each device are different from each other.

Also, the weight of a case of each device increases the weight of a drone, requiring higher thrust, which increases the amount of power consumed, and accordingly, operating time may be reduced.

Accordingly, in solving the above problems, there is an urgent need for technology development regarding a drone integrated control device that prevents incorrect assembly by simplifying wiring, prevents malfunctions due to signal interference by combining transmitted and received signals, and increases power efficiency by lowering power consumption by reducing the weight of each device.

### DISCLOSURE

### Technical Problem

The present invention is to solve the above problems, and a drone integrated control device according to an embodiment of the present invention aims to provide a drone integrated control device that simplifies wiring to prevent incorrect assembly, prevents malfunctions due to signal interference by combining the transmitted and received signals into one, increases power efficiency by reducing the weight of each device, checks a power state of each device, reduces an area of a board, and increases fixing force between a drone and the board.

### Technical Solution

According to an embodiment of the present invention, a drone integrated control device that controls a drone by unifying respective components on one board may include a flight control unit including a plurality of sensors and configured to control a path and a flight attitude of the drone, a motor controller configured to control a rotation speed of at least one motor mounted to the drone to perform movements and takeoffs of the drone, a communication processor configured to transmit and receive control signals input to and output from the respective components included in the drone integrated control device, and a power supply assembly configured to supply power to the respective components included in the drone integrated control device to operate the respective components.

Also, the sensors may include a sensor module including at least one of an acceleration sensor, a gyro sensor, a barometric pressure sensor, a distance sensor, and a vision sensor to detect internal information and external information of the drone, a GPS module configured to measure position coordinates and an altitude of the drone; and a compass module configured to assist the GPS module to correct an error in a center value of the GPS module and to function in lieu of the GPS module when the GPS module does not operate.

Also, the power supply assembly may include a power supplier configured to distribute and supply power, and a power tester configured to supply maximum power to the drone integrated control device for a certain period of time to check a power state of the respective components.

Here, the power tester may include a sensor tester connected to the flight controller to generate lifespan information of the sensors, a motor tester connected to the motor control processor to generate lifespan information of the motor, a communication tester module connected to the communication unit and generating reception strength information by testing a reception strength from a communication terminal, and a display configured to display power test information including at least one of the lifespan information of the sensors, the lifespan information of the motor, and the reception strength information.

Also, the power tester may receive the maximum power from the power supplier, supply power of a standard power consumption amount in the order of the highest standard power consumption among the respective components included in the drone integrated control device, generate the power test information when there is a component that does not receive corresponding power, and transmit the power test information to the display.

Also, the drone integrated control device may further include a plurality of external device mounting portions formed on the board such that at least one external device for performing a certain operation is mounted on the drone.

Here, each of the plurality of external device mounting portions may include a first plate having a first mounting hole in which the external device is mounted, a second plate extended from an edge of the first plate, and configured to rotate and to be folded or unfolded with respect to the edge of the first plate as being a rotational axis, and, and a third plate extended from an edge of the second plate and configured to rotate and to be folded or unfolded with respect to the edge of the second plate as being a rotational axis.

Also, the second plate and the third plate respectively have a second mounting hole and a third mounting hole formed at positions corresponding to the first mounting hole in a state of being folded with the first plate.

Also, the drone integrated control device may further include a plurality of auxiliary fixing portions formed on a lower surface of the board and fixed to the drone to increase fixing force.

Here, each of the plurality of auxiliary fixing portions may include a sliding guide formed in a cylindrical shape having a length, including an accommodation portion therein, and having insertion holes formed at regular intervals on one side of the accommodation portion, and a fixing member formed in a columnar shape having a length, rotatable while inserted into the accommodation portion, and including a body portion having a fixing protrusion formed on a side thereof and a head portion extending at a certain angle from an end of the body portion

Also, a length of the fixing member being pulled in from the sliding guide may be adjusted, and as the body portion rotates internally by rotation of the head portion, the fixing protrusion may be inserted into one of the insertion holes to fix the length.

### Advantageous Effects

A drone integrated control device according to an embodiment of the present invention prevents incorrect assembly by simplifying wiring by unifying one or more components on one board.

Also, by unifying the transmitted and received signals, malfunctions due to signal interference are prevented.

Also, power efficiency is increased by reducing the weight of each component.

Also, a power state of one or more components unified in the drone integrated control device is checked.

Also, a board area is reduced to facilitate board installation.

Also, fixing force between a drone and a board is increased.

### DESCRIPTION OF DRAWINGS

FIG. 1 is a block diagram illustrating a configuration of a drone integrated control device according to an embodiment of the present invention.

FIG. 2 is a block diagram illustrating a configuration of a flight control unit of FIG. 1.

FIG. 3 is an example view illustrating the drone integrated control device of FIG. 1.

FIG. 4 is a block diagram illustrating a configuration of a power supply unit according to an embodiment of the present invention.

FIG. 5 is a block diagram illustrating a configuration of a power tester unit of FIG. 4.

FIG. 6 is a perspective view illustrating a drone integrated control device according to an embodiment of the present invention, in which an external device mounting portion is formed.

FIGS. 7A to 7C are example views illustrating the external device mounting portion of FIG. 6 which is extended.

FIG. 8 is a perspective view illustrating an auxiliary fixing portion of the drone integrated control device according to the embodiment of the present invention.

FIGS. 9A to 9D are example views illustrating an operation of the auxiliary fixing portion of FIG. 8.

### BEST MODE

According to an embodiment of the present invention, a drone integrated control device that controls a drone by unifying respective components on one board may include a flight control unit including a plurality of sensors and configured to control a path and a flight attitude of the drone, a motor control unit configured to control a rotation speed of at least one motor mounted to perform movement and takeoff of the drone, a communication unit configured to transmit and receive control signals input to and output from the respective components included in the drone integrated control device, and a power supply unit configured to supply power to the respective components included in the drone integrated control device to operate the respective components.

### MODE FOR INVENTION

Hereinafter, descriptions of the present invention made with reference to the drawings are not limited to specific embodiments, and various changes may be made and various embodiments may be derived. Also, the content described below should be understood to include all conversions, equivalents, and substitutes included in the idea and technical scope of the present invention.

In the following description, terms “first”, “second”, and so on are used to describe various components, and their meaning is not limited, and is used only for the purpose of distinguishing one component from other components.

Like reference numerals used throughout the present invention refer to like elements.

As used herein, singular expressions include plural expressions, unless the context clearly dictates otherwise. Also, terms such as “comprise,” “provide,” or “have” used below should be construed as intended to designate the presence of features, numbers, steps, operations, components, portions, or a combination thereof described in the specification and should be understood as not precluding the presence or addition of one or more other features, numbers, steps, operations, components, parts or combinations thereof.

Unless otherwise defined, all terms used herein, including technical or scientific terms, have the same meaning as generally understood by those skilled in the technical field to which the present invention pertains. Terms such as those defined in commonly used dictionaries should be interpreted as having meanings consistent with the meanings they have in the context of the related technology, and should not be interpreted as having ideal or excessively formal meanings, unless explicitly defined in the present application.

Also, when describing with reference to the accompanying drawings, identical components are assigned the same reference numerals regardless of the reference numerals, and overlapping descriptions thereof are omitted. When it is determined that a detailed description of related known technologies may unnecessarily obscure the gist of the present invention in describing the present invention, the detailed descriptions are omitted. Here, the term “module” does not necessarily mean software or algorithms per se, but rather means an assembly of mechanical and/or electrical components which may include processors or circuits configured to execute such software or algorithm.

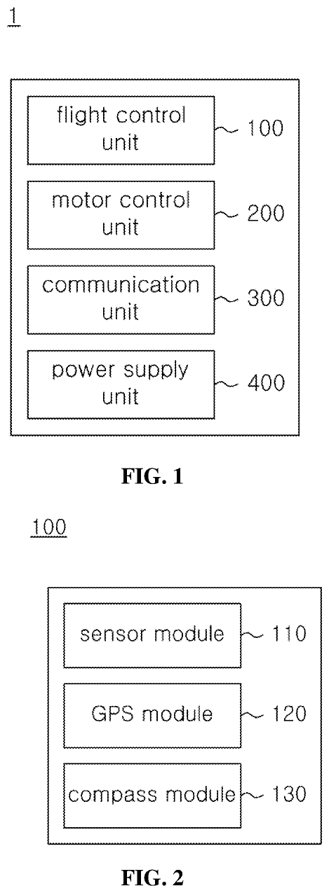

Hereinafter, a drone integrated control device according to an embodiment of the present invention is described in detail with reference to FIGS. 1 to 6, 7A-7C, 8 and 9A-9D.

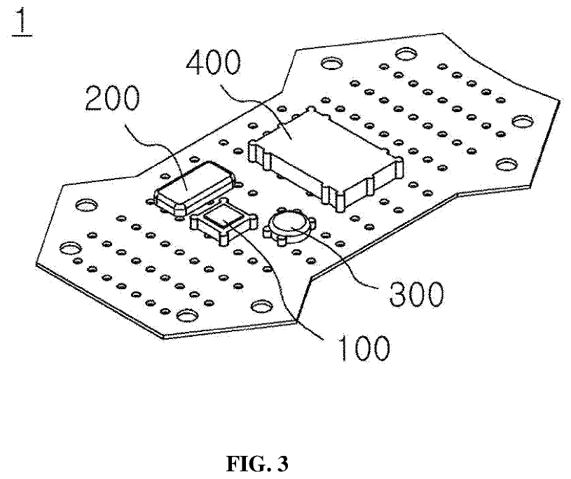

FIG. 1 is a block diagram illustrating a configuration of the drone integrated control device according to the embodiment of the present invention, FIG. 2 is a block diagram illustrating a configuration of a flight control unit of FIG. 1, and FIG. 3 is an example view illustrating the drone integrated control device of FIG. 1.

Referring to FIG. 1, the drone integrated control device 1 according to the embodiment of the present invention may include a flight control unit 100, a motor control unit 200, a communication unit 300, and a power supply unit 400.

Specifically, the drone integrated control device 1 may be formed by unifying the flight control unit 100, motor control unit 200, the communication unit 300, and the power supply unit 400 on one board.

The flight control unit 100 may include a plurality of sensors to control a path and a flight attitude of a drone.

Specifically, referring to FIG. 2, the flight control unit 100 may include a sensor module 110, a GPS module 120, and a compass module 130.

First, the sensor module 110 is composed of one or more sensors among an acceleration sensor, a gyro sensor, a barometric pressure sensor, a distance sensor, and a vision sensor, and may detect internal information and external information of a drone.

Here, the acceleration sensor may determine tilt information and angle information of a drone at a stationary position by measuring acceleration information applied to the drone in three axes X, Y, and Z, and may calculate a speed, a direction, and an altitude change of the drone by measuring linear acceleration information in a horizontal direction and a vertical direction.

Also, the gyro sensor may measure the angular velocity information applied to drone in three axes (pitch, roll, and yaw), maintain the drone's balance by utilizing the angular velocity information, and allow a user to rotate the drone in a direction that the user want to control.

Also, the barometric pressure sensor may measure the air pressure outside the drone, convert the measured barometric pressure into altitude information, and causes the drone to ascend or descend by using the altitude information.

Also, the distance sensor may measure distance information between the drone and the ground or the distance information between the drone and an object, adjust an ascent height and a descent height of the drone by using the distance information, and calculate a distance to the object.

Also, the vision sensor may measure obstacle information by detecting an obstacle around the drone and prevent collision with the obstacle by using the obstacle information.

Next, the GPS module 120 may measure position coordinates and an altitude of the drone.

Specifically, the GPS module 120 may measure a distance between a satellite and the GPS module 120 through radio waves transmitted toward the ground in real time from a plurality of satellites, and calculate the position coordinates and the altitude of the drone through an average of the distances measured by each satellite.

Next, the compass module 130 may assist the GPS module 120 to correct a center value, and when the GPS module 120 does not operate, the compass module 130 may function on behalf of the GPS module 120.

Specifically, the compass module 130 is a module that operates as a compass for the drone and may measure the drone's bearing information based on magnetic north and correct center value errors of the GPS module 120 caused by power lines that emit electromagnetic waves, a steel structure, and magnetism.

Also, the compass module 130 is difficult to be used instead of the GPS module 120 because magnetic north may not be measured above 70 degrees north latitude, making it difficult to measure azimuth information, but may be used instead of the GPS module 120 below 70 degrees north latitude.

The motor control unit 200 may control a rotation speed of one or more motors mounted to perform movement and takeoff of a drone.

Specifically, the motor control unit 200 may control a motor by changing a voltage applied to the motor by generating a pulse that turns on or off drive power at regular intervals by using a pulse width modulation (PWM) control method but is not limited thereto and may be controlled by various types of control methods, such as a PID control method using proportionality, integration, and differentiation, and a linear control method for adjusting an analog voltage.

The communication unit 300 may transmit and receive control signals input to or output from respective components included in the drone integrated control device 1.

Here, the communication unit 300 can be a processor or circuit which may receive a control signal from a user's communication terminal and transmit the control signal to respective components included in the drone integrated control device 1, and when receiving a control signal from the drone, the communication unit 300 may transmit a control signal to the communication terminal.

Specifically, the communication unit 300 may transmit and receive control signals by using various methods, such as Bluetooth serial communication which is a short-distance low-power wireless communication method, Wi-Fi communication through a wireless LAN, satellite communication through a satellite, and cellular communication through a base station of mobile wireless communication.

The power supply unit 400 may supply power to respective components included in the drone integrated control device.

Specifically, the power supply unit 400 may use LiPo (lithium polymer), LiFe (lithium iron), LiIon (lithium ion), NiMH (nickel hydrogen), NiCd (nickel cadmium), NiZn (nickel zinc), and so on as a battery that supplies power to the drone integrated control device 400 but is not limited to this and may use various types of batteries that may supply power.

To summarize with reference to FIG. 3, the drone integrated control device 1 may be characterized in that the components described above are unified on one board.

Accordingly, the drone integrated control device 1 may simplify wiring by connecting respective components directly to a board without using wires to connect the respective components, thereby preventing incorrect assembly of the respective components to be assembled in the drone.

Also, the drone integrated control device 1 is connected to one board such that one signal is used, thereby preventing abnormal operation due to signal interference.

Also, because the respective components of the drone integrated control device 1 do not include components, such as a case for holding the frame and a plurality of wires provided to connect the respective components to each other, weights of the respective components may be reduced, which may reduce the weight of the entire board, and thus, power efficiency is increased.

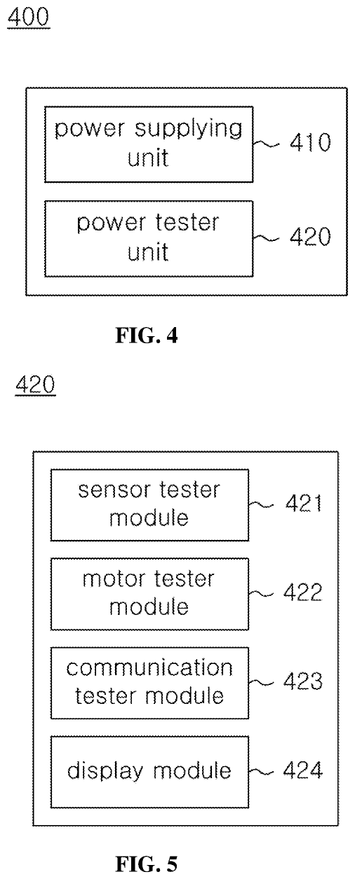

FIG. 4 is a block diagram illustrating a configuration of a power supply unit according to an embodiment of the present invention, and FIG. 5 is a block diagram illustrating a configuration of a power tester unit of FIG. 4.

Referring to FIG. 4, the power supply unit 400 according to an embodiment of the present invention may include a power supplying unit 410 and a power tester unit 420.

First, the power supplying unit 410 may distribute and supply power.

Specifically, the power supplying unit 410 may distribute power by adjusting the amount of power required by respective components included in the drone integrated control device 1, and thus, it is possible to prevent overpower or underpower from being supplied to the respective components.

The power tester unit 420 may supply maximum power to the drone integrated control device 1 for a certain period of time, and thereby, a power state of the drone may be checked.

Specifically, referring to FIG. 5, the power tester unit 420 may include a sensor tester module 421, a motor tester module 422, a communication tester module 423, and a display module 424.

First, the sensor tester module 421 may be connected to the flight control unit 100 and generate lifespan information of a sensor.

Here, the sensor is preferably one of the sensor module 110, the GPS module 120, and the compass module 130.

Specifically, the sensor tester module 421 supplies power to each sensor such that each sensor reaches a standard power consumption, and when there is a sensor that does not reach the standard power consumption, the sensor tester module 421 measures the power supplied to the sensor and generate the lifespan information of the sensor.

More specifically, the sensor tester module 421 may set 0.5% of the maximum power consumption of a sensor as a discharge error and divide the supplied power by the standard power consumption, convert a value obtained by adding or subtracting the discharge error to or from a value obtained by the dividing into a percentage value, thereby generating the lifespan information of the sensor.

For example, in a case of a sensor with a maximum power consumption of 4 W and a standard power consumption of 3 W and a supplied power of 2 W, lifespan information of 64% or 68% of a sensor may be generated by calculating 0.66 obtained by dividing the supplied power of 2 W by the standard power consumption of 3 W, calculating a discharge error of 0.02 which is 2% of the maximum power consumption of 4 W, and converting a value obtained by adding or subtracting the discharge error of 0.02 to or from 0.66 which is a value obtained by dividing the supplied power by the standard power consumption into a percentage value.

In this case, when the lifespan information of a sensor is less than 20%, the lifespan information of a sensor may be displayed on the display module 424 along with a sensor replacement notification.

Due to this, it is possible to check the lifespan information of a sensor in the drone and determine when to replace the sensor.

Next, the motor tester module 422 may be connected to the motor control unit 200 to generate lifespan information of a motor.

Specifically, the motor tester module 422 may gradually supply power to a motor to reach standard power consumption and measure power, rotation speed, and heat temperature of the motor, thereby generating lifespan information of the motor.

More specifically, the motor tester module 422 may generate power lifespan information of a motor by dividing the supplied power by the measured standard power consumption and converting a value obtained by the dividing into a percentage value.

Also, the motor tester module 422 may generate rotation speed lifespan information of a motor by dividing the measured rotation speed by the standard rotation speed of the motor and converting a value obtained by the dividing into a percentage value.

Also, the motor tester module 422 may generate heat generation temperature lifespan information of a motor by converting a value obtained by subtracting a standard heat generation temperature from a measured heat generation temperature of the motor into an absolute value.

For example, in a case of a motor with a standard power consumption of 10 W and a supplied power of 8 W, 0.8, 80% of power lifespan information of the motor may be generated by calculating 0.8 which is a value obtained by dividing the supplied power of 8 W by the standard power consumption of 10 W and converting the value of 0.8 into a percentage value.

In this case, when the power lifespan information of a motor is less than 20%, the motor tester module 422 may display the power lifespan information of the motor on the display module 424 along with a motor replacement notification.

Also, when a standard rotation speed of a motor is 8000 RPM and a measured rotation speed is 6000 RPM, power lifespan information of 81.25% of the motor may be generated by calculating 0.8125 which is a value obtained by dividing a measured rotation speed of 6000 RPM by the standard rotation speed of 8000 RPM and converting the value of 0.8125 into a percentage value.

In this case, when the standard rotation speed lifespan information of a motor is less than 30%, the motor tester module 422 may display the rotation speed lifespan information of the motor on the display module 424 along with a motor replacement notification.

Also, when a standard heating temperature of a motor is 38° C. and a measured heating temperature is 45° C., heat generation temperature lifespan information of 7 of the motor may be generated by calculating 7 which is a value obtained by subtracting the standard heating temperature of 38° C. from the measured heating temperature of 45° C. and converting the value of 7 into an absolute value.

In this case, when the heat generation temperature lifespan information of the motor exceeds 5, the motor tester module 422 may display the heat generation temperature lifespan information of the motor on the display module 424 along with a motor replacement notification.

Next, the communication tester module 423 may be connected to the communication unit 300 and may test a reception strength with a communication terminal, thereby generating reception strength information.

Specifically, the communication tester module 423 outputs a test radio wave of a maximum output from the communication unit 300, and the test radio wave is a radio wave that returns to the place from which the test radio wave is initially output when transmitted to a communication terminal, and by measuring a signal strength of returned test radio wave, reception strength information may be generated.

More specifically, the communication tester module 423 may generate reception strength information by dividing an output strength of the returned test radio wave by an output strength of the initially transmitted test radio wave and converting a value obtained by the dividing into a percentage value.

For example, when a test radio wave with a frequency of 2.4 GHz is transmitted to a communication terminal with an output of 1 W and a strength of the test radio wave returned to the communication unit 300 through the communication terminal is 0.7 W, reception intensity information of 70% may be generated by converting 0.7 which is a value obtained by dividing 0.7 W which is a strength of the returned test radio wave by a strength of 1W of the initially output test radio wave into a percentage value.

In this case, when the reception strength information is less than 30%, the communication tester module 423 may display the reception strength information on the display module 424 along with a replacement notification of a communication terminal battery or a communication unit.

Next, the display module 424 may display power test information including one piece or more pieces of the measured lifespan information of a sensor, the lifespan information of a motor, and the reception strength information.

Due to this, it is possible to check a power state of one or more devices unified in the drone integrated control device 1.

Also, the power tester unit 420 may receive the maximum power from the power supply unit 400 and supply power of the maximum power consumption in the order of the maximum power consumption among respective components included in the drone integrated control device 1, and when there is a component not received the corresponding power, the power tester unit 420 may generate power test information and transmit the power test information to the display module 424.

In this case, the power tester unit 420 may display a replacement notification of the power supply unit 400 on the display module 424.

Due to this, a user may know when to replace a battery of the power supply unit 400.

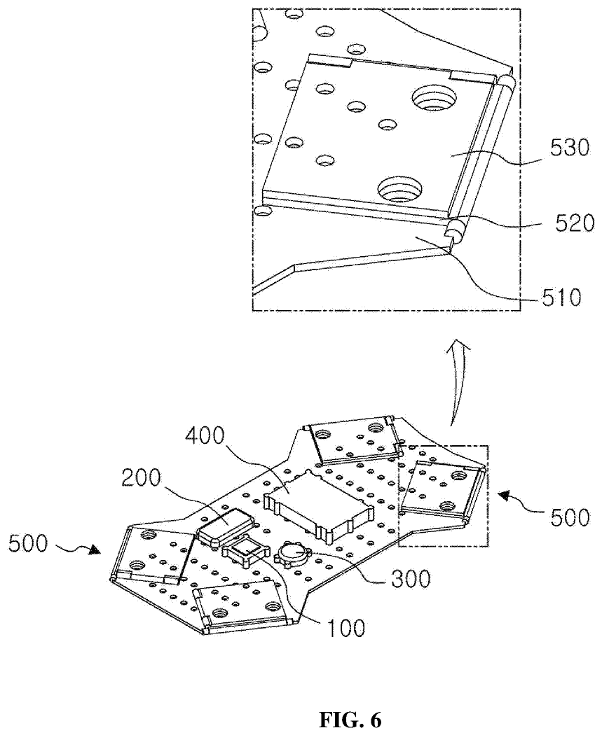

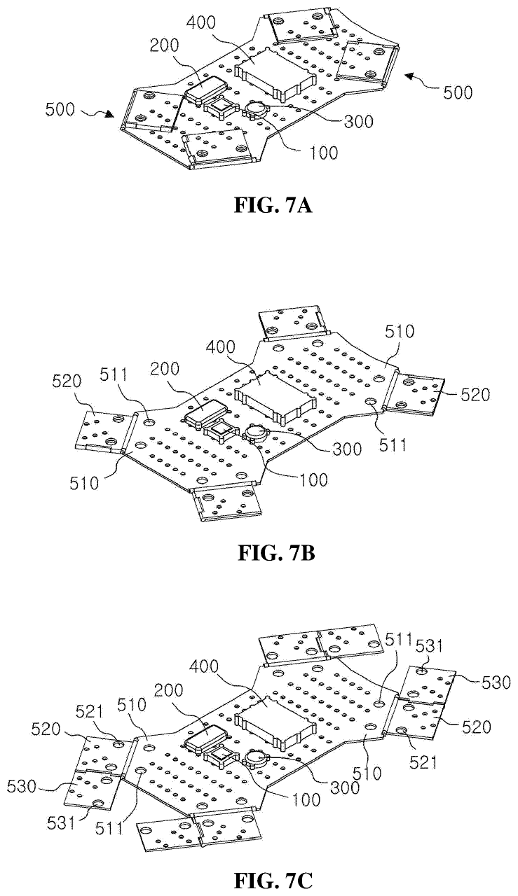

FIG. 6 is a perspective view illustrating a drone integrated control device according to an embodiment of the present invention, in which an external device mounting portion is formed and FIGS. 7A to 7C are example views illustrating the external device mounting portion of FIG. 6 which is extended.

Referring to FIG. 6, the drone integrated control device 1 according to the embodiment of the present invention may further include an external device mounting portion 500.

The external device mounting portion 500 may be one or more external device mounting portions formed on a board to cause a drone to perform a certain operation.

Also, the external device mounting portion 500 may include a first plate 510, a second plate 520, and a third plate 530.

First, the first plate 510 may be formed on a board of the drone integrated control device 1 and have a first mounting hole 511 on which an external device is mounted.

Next, the second plate 520 is formed to extend from an edge of the first plate 510 and may be bent with an edge of the first plate 510 as a central axis to be formed in a foldable manner

Here, the second plate 520 may have a second mounting hole 521 formed at a position corresponding to the first mounting hole 511 while being overlapped with the first plate 510.

Next, the third plate 530 is formed to extend from an edge of the second plate 520 and may be bent with an edge of the second plate 520 as a central axis to be formed in a foldable manner.

Here, the third plate 530 may have a third mounting hole 531 at a position corresponding to the first mounting hole 511 and the second mounting hole 521 while being overlapped with the first plate 510 and the second plate 520.

In this case, an edge where respective plates are connected to each other to form a central axis is formed as a hinge to rotate the respective plates such that the respective plates may be folded, overlapped, or unfolded.

Here, the hinge may be formed of an insulating material, such as phenol or epoxy resin but is not limited thereto.

Also, when the first plate 510, the second plate 520, and the third plate 530 are formed to be overlapped, the first mounting hole 511, the second mounting hole 521, and the third mounting hole 531 may be connected to each other like a single hole.

Hereinafter, an operation of the external device mounting unit 500 is described with reference to FIGS. 7A-7C.

First, referring to FIG. 7A, in a state where the first plate 510, the second plate 520, and the third plate 530 are all overlapped with each other, one external device may be mounted to penetrate all of the first mounting hole 511, the second mounting hole 521, and the third mounting hole 531.

Next, referring to FIG. 7B, the second plate 520 may extend from the first plate 510 in an unfolded state, an external device may be mounted in the first mounting hole 511 in a state where the third plate 530 is overlapped with the second plate 520, and an external device of another object may be mounted to penetrate the second mounting hole 521 and the third mounting hole 531 which are overlapped with each other.

Thereafter, the third plate 530 may be unfolded from the second plate 520 to be in a state as illustrated in FIG. 7C, and accordingly, the drone integrated control device 1 may cause one external device to be mounted in the first mounting hole 511, an external device of another object to be mounted in the second mounting hole 521, and an external device of another object to be mounted in the third mounting hole 531.

Also, in the external device mounting portion 500, the first plate 510, the second plate 520, and the third plate 530 may have guide grooves respectively formed therein, and may be electrically connected to a board by filling the guide grooves with lead.

Due to this, an area of the board installed on a drone may be reduced to facilitate installation of the board.

Also, according to a user's request, the area of the board may be widened to facilitate installation of an external device.

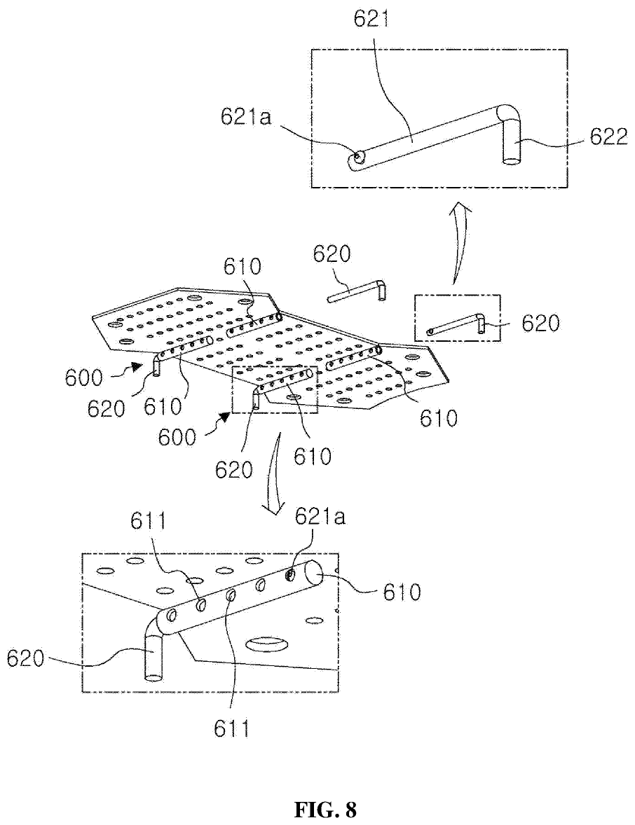

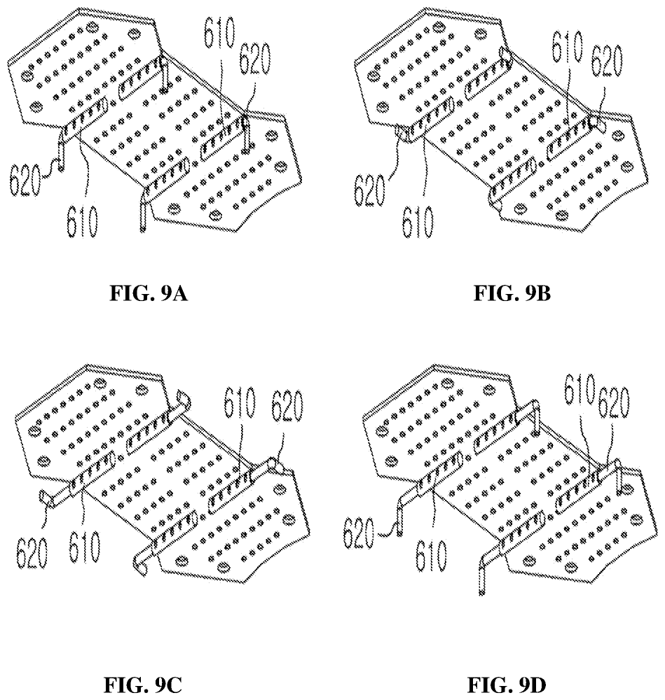

FIG. 8 is a perspective view illustrating an auxiliary fixing portion of the drone integrated control device according to the embodiment of the present invention, and FIGS. 9A-9D are example views illustrating an operation of the auxiliary fixing portion of FIG. 8.

Referring to FIG. 8, the drone integrated control device 1 according to an embodiment of the present invention may further include an auxiliary fixing portion 600.

The auxiliary fixing portion 600 may include a plurality of auxiliary fixing portions formed on a lower surface of the board and may be fixed to the drone to increase fixing force.

Also, the auxiliary fixing portion 600 may include a sliding guide 610 and a fixing member 620.

First, the sliding guide 610 may be formed in a cylindrical shape having a certain length and have an accommodation portion therein, and fitting holes 611 may be formed at regular intervals on one side of the accommodation portion.

Due to this, the fixing member 620 may be pulled in along a length of the accommodation portion of the sliding guide 610.

Next, the fixing member 620 may be configured to include a body portion 621 and a head portion 622.

Here, the body portion 621 may be formed in a columnar shape having a certain length and may rotate while inserted into the accommodation portion, and a fixing protrusion 621a may be formed on a side thereof.

Due to this, the fixing protrusion 621a may be inserted into the fitting hole 611 to fix a portion of a certain length that is pulled in along the sliding guide 610.

Also, the head portion 622 is preferably formed at a right angle from an end of the body portion 621 but is not limited thereto and the head portion 622 may be formed to extend at a certain angle.

Due to this, the fixing member 620 is prevented from fully introducing into the accommodation portion, and rotation of the body portion 621 through the head portion 622 may be facilitated.

In conclusion, a length of the auxiliary fixing portion 600 may be adjusted by being pulled in or out from the sliding guide 610, and the fixing protrusion 621a may be inserted into the fitting hole 611 to be fixed.

Hereinafter, an operation of the auxiliary fixing portion 600 is described with reference to FIGS. 9A-9D.

First, referring to FIG. 9A, as the fixing member 620 is fully pulled in the sliding guide 610, the fixing protrusion 621a may be inserted into the fitting hole 611 and fixed.

Next, referring to FIG. 9B, as the head portion 622 rotates 90°, the body portion 621 also rotates, and accordingly, the fixing protrusion 621a may be separated from the fitting hole 611.

Next, referring to FIG. 9C, the fixing member 620 may be pulled out from the sliding guide 610 and extended.

Next, referring to FIG. 9D, as the head portion 622 rotates 90°, the body portion 621 also rotates, and accordingly, the fixing protrusion 621a may be inserted into the fitting hole 611 and an extended length may be fixed.

Due to this, the auxiliary fixing portion 600 may have a variable length to suit an area of a drone according to a user's request and may be fixed in a varied state to increase the fixing force between a board and the drone.

In this case, the head portion 622 may further include a housing (not illustrated) surrounding an outer surface.

The housing (not illustrated) is formed such that the auxiliary fixing portion 600 may come into closer contact with a drone and may be formed of an elastic material, most preferably silicone but is not limited thereto.

Accordingly, the auxiliary fixing portion 600 is fixed in close contact with a drone, and thereby, it is possible to prevent a board from being separated from or shaking inside the drone, and the drone may fly safely.

The embodiments of the present invention described above are not implemented only through devices and/or methods, but may be implemented through programs for realizing functions corresponding to the configuration of the embodiments of the present invention, recording media on which the programs are recorded, and so on, and this implementation may be easily implemented by an expert in the technical field to which the present invention belongs based on the description of the embodiments described above.

Also, although the embodiments of the present invention are described in detail above, the scope of the present invention is not limited thereto, and various modifications and improvements may also be made by those skilled in the art using the basic concept of the present invention defined in the following claims and fall within the scope of invention rights.

### EXPLANATION OF REFERENCE NUMERALS

1: drone integrated control device
100: flight control unit
110: sensor module
120: GPS module
130: compass module
200: motor control unit
300: communication unit
400: power supply unit
410: power supplying unit
420: power tester unit
421: sensor tester module
422: motor tester module
423: communication tester module
424: display module
500: external device mounting portion
510: first plate
511: first mounting hole
520: second plate
521: second mounting hole
530: third plate
531: third mounting hole
600: auxiliary fixing portion
610: sliding guide
611: insertion hole
620: fixing member
621: body portion
621a: fixing protrusion
622: head portion

1. A drone integrated control device that controls a drone by unifying respective components on one board, the drone integrated control device comprising:
a flight control unit including a plurality of sensors and configured to control a path and a flight attitude of the drone;
a motor controller configured to control a rotation speed of at least one motor mounted to the drone to perform movements and takeoffs of the drone;
a communication processor configured to transmit and receive control signals input to and output from the respective components included in the drone integrated control device; and
a power supply assembly configured to supply power to the respective components included in the drone integrated control device to operate the respective components.

2. The drone integrated control device of claim 1, wherein the plurality of sensors includes at least one of an acceleration sensor, a gyro sensor, a barometric pressure sensor, a distance sensor, and a vision sensor to detect internal information and external information of the drone, and
wherein the flight control unit further includes:
a GPS configured to measure position coordinates and an altitude of the drone; and
a compass configured to correct an error in a center value of the GPS and to function in lieu of the GPS when the GPS does not operate.

3. The drone integrated control device of claim 1, wherein the power supply assembly includes:
a power supplier configured to distribute and supply power; and
a power tester configured to supply maximum power to the drone integrated control device for a certain period of time to check a power state of the respective components,
wherein the power tester includes:
a sensor tester connected to the flight control unit to generate lifespan information of the plurality of sensors;
a motor tester connected to the motor controller to generate lifespan information of the at least one motor;
a communication tester connected to the communication processor and generating reception strength information by testing a reception strength from a communication terminal; and
a display configured to display power test information including at least one of the lifespan information of the plurality of sensors, the lifespan information of the at least one motor, and the reception strength information.

4. The drone integrated control device of claim 3, wherein
the power tester receives the maximum power from the power supplier, supplies power of a standard power consumption amount in the order of the highest standard power consumption among the respective components included in the drone integrated control device, generates the power test information when there is a component that does not receive corresponding power, and transmits the power test information to the display.

5. The drone integrated control device of claim 1, further comprising:
a plurality of external device mounting portions formed on the one board such that at least one external device for performing an operation is mounted on the drone,
wherein each of the plurality of external device mounting portions includes:
a first plate having a first mounting hole in which the at least one external device is mounted;
a second plate extended from an edge of the first plate, and configured to rotate and to be folded or unfolded with respect to the edge of the first plate as being a rotational axis; and
a third plate extended from an edge of the second plate, and configured to rotate and to be folded or unfolded with respect to the edge of the second plate as being a rotational axis,
the second plate and the third plate respectively have a second mounting hole and a third mounting hole formed at positions corresponding to the first mounting hole in a state of being folded with the first plate.

6. The drone integrated control device of claim 1, further comprising:
a plurality of auxiliary fixing portions formed on a lower surface of the one board and fixed to the drone to increase fixing force,
wherein each of the plurality of auxiliary fixing portions includes:
a sliding guide formed in a cylindrical shape having a length, including an accommodation portion therein, and having insertion holes formed at regular intervals on one side of the accommodation portion; and
a fixing member formed in a columnar shape having a length, rotatable while inserted into the accommodation portion, and including a body portion having a fixing protrusion formed on a side thereof and a head portion extending at an angle from an end of the body portion, and
wherein a length of the fixing member being pulled in from the sliding guide is adjustable, and as the body portion rotates internally by rotation of the head portion, the fixing protrusion is inserted into one of the insertion holes to fix the length.
